(19) United States
(12) Patent Application Publication
(10) Pub. No.: US 2018/0062010 A1
(43) Pub. Date: Mar. 1, 2018

(54) ARC-BENDING TRANSLUCENT ASSEMBLY, USE AND METHOD FOR MANUFACTURING THEREOF

(71) Applicant: NEXPOWER TECHNOLOGY CORPORATION, Taichung City (TW)

(72) Inventors: Chia-Ling LEE, Taichung City (TW); Yung-Lin CHEN, Taichung City (TW); Jia-Ming LEE, Taichung City (TW)

(21) Appl. No.: 15/690,302

(22) Filed: Aug. 30, 2017

(30) Foreign Application Priority Data
Aug. 31, 2016 (TW) 105128090

(51) Int. Cl. H01L 31/048; H05K 1/02; H05K 3/00; H01L 31/046; H01G 9/20; H01L 51/44

(52) U.S. Cl. CPC H01L 31/048; H05K 1/028; H05K 3/0011; H01L 31/0488; H01G 9/2068; H01L 51/448; H01L 31/046

(57) ABSTRACT

An arc-bending translucent assembly is disclosed in the present disclosure. The arc-bending translucent assembly includes a first substrate and a second substrate. The first substrate has a first thickness and a second thickness at two sides thereof. The first substrate further includes a first arc surface and a second arc surface, in which a third thickness exists between a first top of the first arc surface and a second top of the second arc surface. The third thickness is larger than the first thickness or the second thickness. The second substrate is bent and disposed close to the second arc surface of the first substrate.

### RELATED APPLICATIONS

This application claims priority to Taiwan Application Serial Number 105128090, filed Aug. 31, 2016, which is herein incorporated by reference.

### BACKGROUND

### Technical Field

The present disclosure relates to an arc-bending translucent assembly. More particularly, the present disclosure relates to an arc-bending translucent assembly with a non-uniform substrate thickness, the use and the method for manufacturing thereof.

### Description of Related Art

In general, a glass is a material that is transparent, brittle, air-tight and has a certain hardness. For the feature of being transparent, the glass is widely adopted as the translucent materials in many fields. A laminated glass is made by adding an encapsulation material which is robust and thermoplastic between two pieces of glasses in an environment with high temperature and high pressure. The laminated glass is less possible to be penetrated when experiencing impacts, and the shatter of the laminated glass will be less possible to be spread all around after being damaged. Therefore, the laminated glass is more shock resistant, anti-theft, explosion-proof, and bullet-proof than other kinds of glasses. Moreover, the object between the two pieces of glasses (e.g., the type of the encapsulation material) may improve the functionality of the laminated glass, such as color, sound isolation, anti-infrared, and anti-ultraviolet, etc.

Solar power has been the mainstream of green energy. Along with the development of technologies, more and more industries have created products related to solar powers. A thin film solar cell has advantages such as aesthetical appearance, low temperature factor, and weak light effects, etc. Moreover, the thin film solar cell can be deposited onto a base with large surface (e.g., a glass) to collect infinite solar energy, which makes the thin film solar cell important in the photovoltaic field. More specifically, the combination of the thin film solar cell and the glass has been widely deployed in many applications, such as the building integrated photovoltaic (BIPV) system which gives intelligence to buildings, such that the goal of sustainable development of cities can be gradually achieved. Alternatively, the thin film solar cell can be deployed in a vehicular solar glass (e.g., a sunroof), which is a new product that complies with the trends of energy-saving and low-carbon environment.

However, there are yield problems to be solved while manufacturing the aforementioned applications. For example, when the glass is used as a vehicular sunroof, the surface thereof is usually curved. One of the method is to firstly deposit the thin film solar cell onto a glass whose thickness is extremely thin, and then combined with the vehicular glass via laminating. Since the extremely thin glass whose thickness is lower than 1 mm is flexible, the extremely thin glass can fit the curved surface of the vehicular glass. However, this way is only applicable for those vehicular glasses which are slightly curved. When the sizes of the sunroofs get larger and larger, the sunroof glasses bend more and more, especially for the dome-shaped sunroof. In this case, the edges of the extremely thin glass will be broken for taking too much stress if the extremely thin glass fits the sunroof glasses via the aforementioned ways. On the other hand, the center of the sunroof glasses may also fit the extremely thin glass incompletely, such that a bubble or a hollowing may be generated.

In addition, there is another way that directly forms the thin film solar cell onto a curved glass. In this case, the extremely thin glass may be prevented from being broken when fitting the glass. However, since the conventional manufacturing platforms are designed for flat glass, the cost of modifying the platforms will be higher if the thin film solar cell are directly formed onto the curved glass, and the subsequent promotions will be obstructed.

Accordingly, it is crucial for people with ordinary in the art to design a translucent assembly that can reduce the possibility of glasses breaking while the glasses experiencing a laminating process, such that the yield may be improved.

### SUMMARY

The present disclosure provides an arc-bending translucent assembly including a first substrate and a second substrate. The first substrate has a first thickness and a second thickness at two sides of the first substrate, wherein the first substrate has a first arc surface and a second arc surface opposite to the first arc surface, a third thickness exists between a first top of the first arc surface and a second top of the second arc surface, and the third thickness is larger than the first thickness or the second thickness. The second substrate is bent and disposed dose to the second arc surface of the first substrate. Two sides of the second arc surface are located at a plane, a normal distance exists between the first top of the first arc surface and the plane, and when the third thickness is A and the normal distance is B, the following condition is satisfied: 0 cm≦B−A≦5 cm.

In one embodiment of the present disclosure, at least one of the first thickness and the second thickness is smaller than or equal to 10 mm.

In one embodiment of the present disclosure, the first substrate and the second substrate are made of a glass or a polymer.

In one embodiment of the present disclosure, the arc-bending translucent assembly further includes an encapsulation material laminating the second substrate with the second arc surface of the first substrate.

In one embodiment of the present disclosure, the encapsulation material is chosen from ethylene vinyl acetate copolymer, polyvinyl butyral, polyolefin elastomer copolymer, or polyvinyl fluoride.

In one embodiment of the present disclosure, a transmittance rate of the arc-bending translucent assembly at visible light region is higher than 10%.

In one embodiment of the present disclosure, a transmittance rate of the arc-bending translucent assembly at the wavelength of 550 nm is higher than 10%.

The present disclosure provides an arc-bending translucent assembly used at a top of a vehicle. The arc-bending translucent assembly includes a first substrate, a second substrate, and a photovoltaic conversion module. The first substrate has a first thickness and a second thickness at two sides of the first substrate, wherein the first substrate has a first arc surface and a second arc surface opposite to the first arc surface, a third thickness exists between a first top of the first arc surface and a second top of the second arc surface, and the third thickness is larger than the first thickness or the second thickness. The second substrate is bent and has a third arc surface and a fourth arc surface, wherein the third arc surface faces the second arc surface of the first substrate. The photovoltaic conversion module is disposed between the second arc surface of the first substrate and the third arc surface of the second substrate. Two sides of the second arc surface are located at a plane, a normal distance exists between the first top of the first arc surface and the plane, and when the third thickness is A and the normal distance is B, the following condition is satisfied: 0 cm≦B−A≦5 cm.

In one embodiment of the present disclosure, at least one of the first thickness and the second thickness is smaller than or equal to 10 mm.

In one embodiment of the present disclosure, the first substrate and the second substrate are made of a glass or a polymer.

In one embodiment of the present disclosure, the photovoltaic conversion module includes a plurality of solar cells, and the solar cells are disposed on the second arc surface of the first substrate or the third arc surface of the second substrate.

In one embodiment of the present disclosure, the photovoltaic conversion module includes a third substrate and a plurality of solar cells. The third substrate is disposed between the first substrate and the second substrate. The plurality of solar cells are selectively disposed on a side of the third substrate facing the first substrate or disposed on another side of the third substrate facing the second substrate.

In one embodiment of the present disclosure, the photovoltaic conversion module includes at least one of an amorphous silicon solar cell, a microcrystalline silicon solar cell, a cadmium telluride solar cell, a copper indium selenide solar cell, a copper indium gallium diselenide solar cell, an organic photovoltaic cell, and a dye sensitized solar cell.

In one embodiment of the present disclosure, a transmittance rate of the arc-bending translucent assembly at visible light region is higher than 10%.

In one embodiment of the present disclosure, a transmittance rate of the arc-bending translucent assembly at the wavelength of 550 nm is higher than 10%.

The present disclosure provides a use of the arc-bending translucent assembly, wherein the arc-bending translucent assembly is installed on a car window or on a building surface.

The present disclosure provides a manufacturing method of the arc-bending translucent assembly. The method includes the following steps: manufacturing the first substrate; manufacturing the second substrate; and performing a laminating step to press and bond the second substrate with the first substrate.

In one embodiment of the present disclosure, the first substrate is made by processing a plate or combining a plurality of the plates.

### BRIEF DESCRIPTION OF THE DRAWINGS

The present disclosure can be more fully understood by reading the following detailed description of the embodiment, with reference made to the accompanying drawings as follows:

FIG. 1 is a cross-sectional view of an arc-bending translucent assembly of a first implementation of the present disclosure;

FIG. 2 is a cross-sectional view of a first substrate of FIG. 1;

FIG. 3 is a cross-sectional view of an arc-bending translucent assembly of a second implementation of the present disclosure;

FIG. 4A is a cross-sectional view of the photovoltaic conversion module of FIG. 3 according to a first embodiment of the present disclosure;

FIG. 4B is a cross-sectional view of the photovoltaic conversion module of FIG. 3 according to a second embodiment of the present disclosure;

FIG. 4C is a cross-sectional view of the photovoltaic conversion module of FIG. 3 according to a third embodiment of the present disclosure;

FIG. 4D is a cross-sectional view of the photovoltaic conversion module of FIG. 3 according to a fourth embodiment of the present disclosure; and

FIG. 5 is a flow chart of the manufacturing method of the arc-bending translucent assembly of the present disclosure.

### DETAILED DESCRIPTION

One of the goals of the present disclosure is to propose an arc-bending translucent assembly including a first substrate and a second substrate, wherein the first substrate is a substrate with a non-uniform thickness. Accordingly, the breaking issue of the translucent assembly during a laminating process can be reduced. In particular, the first substrate can be made of a glass or a polymer, but the present disclosure is not limited thereto.

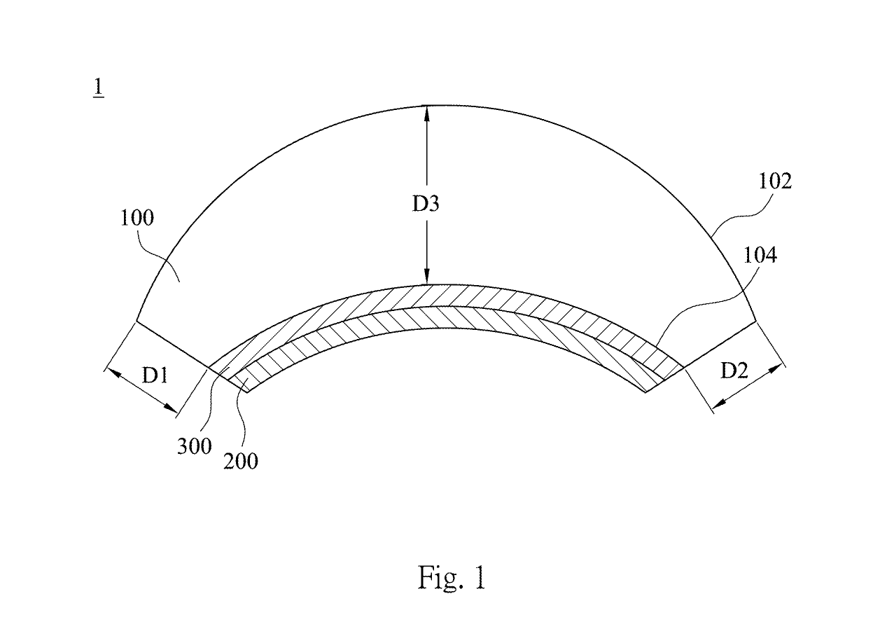

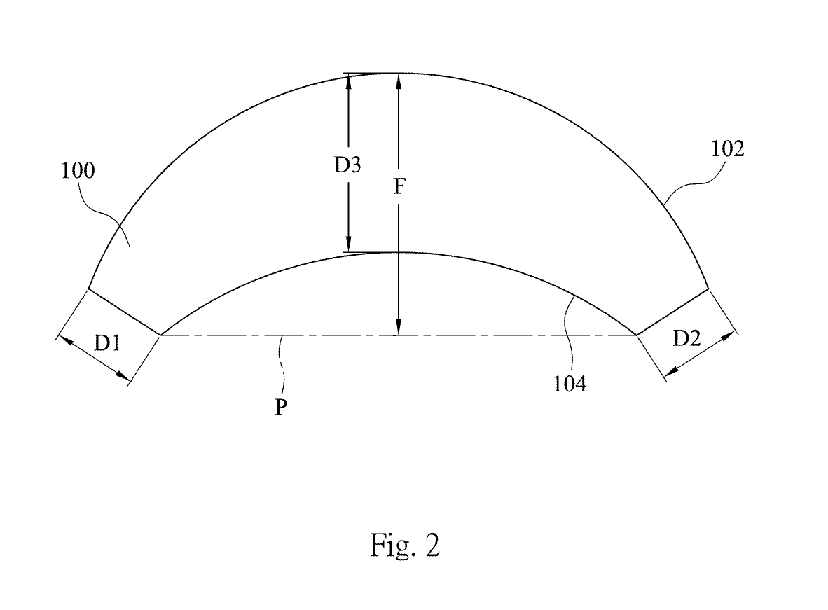

See FIG. 1 and FIG. 2, wherein FIG. 1 is a cross-sectional view of an arc-bending translucent assembly 1 of a first implementation of the present disclosure, and FIG. 2 is a cross-sectional view of a first substrate 100 of FIG. 1. As shown in FIG. 1, the arc-bending translucent assembly 1 includes the first substrate 100 and a second substrate 200. The first substrate 100 has a first thickness D1 and a second thickness D2 at two sides of the first substrate 100, wherein the first substrate 100 has a first arc surface 102 and a second arc surface 104 opposite to the first arc surface 102. The first arc surface 102 has a first top, the second arc surface 104 has a second top, and a third thickness D3 exists between the first top of the first arc surface 102 and the second top of the second arc surface 104.

See FIG. 2 for further details. In FIG. 2, the first substrate 100 is a glass substrate with a non-uniform thickness. More particularly, the first substrate 100 is a glass substrate whose middle thickness is thicker than edge sides of the first substrate 100. That is, the third thickness D3 is larger than the first thickness D1 or the second thickness D2. Besides, the first thickness D1 may be equal or unequal to the second thickness D2, but the present disclosure is not limited thereto. For example, at least one of the first thickness D1 and the second thickness D2 is smaller than or equal to 10 mm.

In addition, two sides of the second arc surface 104 of the first substrate 100 are located at a plane P, and a normal distance F exists between the first top of the first arc surface 102 and the plane P. When the third thickness D3 is A and the normal distance F is B, the following condition is satisfied: 0 cm≦B−A≦5 cm.

See FIG. 1 again, wherein the second substrate 200 is bent and disposed close to the second arc surface 104 of the first substrate 100. Moreover, the second substrate 200 can be made of a glass or a polymer, but the present disclosure is not limited thereto.

Next, the first substrate 100 can be laminated with the second substrate 200 via an encapsulation material 300, and the encapsulation material 300 may be chosen from ethylene vinyl acetate (EVA) copolymer, polyvinyl butyral (PVB), polyolefin elastomer (POE) copolymer, polyvinyl fluoride (PVF), or a combination thereof.

In brief, in the present disclosure, the first substrate 100 having a non-uniform thickness can be used with the second substrate 200 having a uniform thickness, wherein the first substrate 100 and the second substrate 200 can be combined and bent via a laminating step, such that the first arc surface 102 and the second arc surface 104 can be formed on the first substrate 100, and the first thickness D1, the second thickness D2, the third thickness D3, and the normal distance F thereof need to satisfy the aforementioned conditions. As for the manufacturing method of the arc-bending translucent assembly 1, it will be introduced in the following paragraphs. Accordingly, when the arc-bending translucent assembly 1 is used as a vehicular sunroof, the first substrate 100 is used as the external substrate, and the curved surface of the first arc surface 102 may still satisfy the appearance requirement. Meanwhile, the breaking issue during the laminating step can be solved while improving the yield of the manufacturing process.

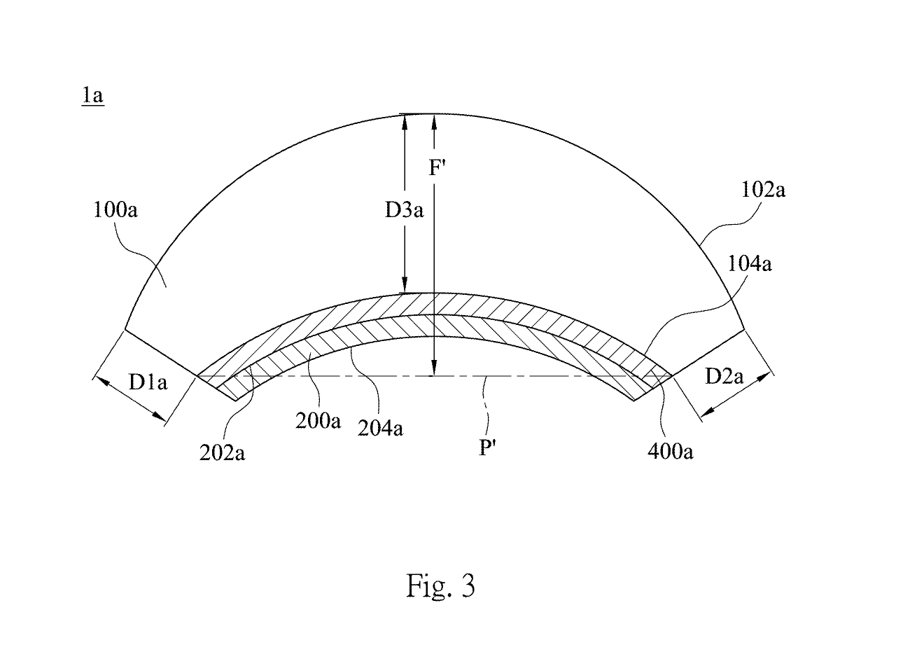

See FIG. 3, which is a cross-sectional view of an arc-bending translucent assembly 1a of a second implementation of the present disclosure. As shown in FIG. 3, the arc-bending translucent assembly 1a includes a first substrate 100a, a second substrate 200a, and a photovoltaic conversion module 400a between the first substrate 100a and the second substrate 200a. The first substrate 100a has a first thickness D1a and a second thickness D2a at two sides of the first substrate 100a, wherein the first substrate 100a has a first arc surface 102a and a second arc surface 104a opposite to the first arc surface 102a. The first arc surface 102a has a first top, the second arc surface 104a has a second top, and a third thickness D3a exists between the first top of the first arc surface 102a and the second top of the second arc surface 104a.

Similar to the first implementation, the third thickness D3a is larger than the first thickness D1a or the second thickness D2a. That is, the first substrate 100a of the second implementation is also a glass substrate whose middle thickness is thicker than edge sides of the first substrate 100a. The first thickness D1a can be, but not limited to, equal to the second thickness D2a. In addition, two sides of the second arc surface 104a of the first substrate 100a are located at a plane P′, and a normal distance F′ exists between the first top of the first arc surface 102a and the plane P′. When the third thickness D3a is A and the normal distance F′ is B, the following condition is also satisfied: 0 cm≦B−A≦5 cm.

In the second implementation, the second substrate 200a is also bent and has a third arc surface 202a and a fourth arc surface 204a, wherein the third arc surface 202a faces the second arc surface 104a of the first substrate 100a. The thickness and the material of the second substrate 200a can be referred to the first implementation, which will not be repeated herein.

Different from the first implementation, the arc-bending translucent assembly 1a of the second implementation includes the photovoltaic conversion module 400a which locates between the second arc surface 104a of the first substrate 100a and the third arc surface 202a of the second substrate 200a. Accordingly, the arc-bending translucent assembly 1a may be deployed at the sunroof on the top of a vehicle or other car windows. Alternatively, the arc-bending translucent assembly 1a may be also installed on a building surface, such that the goal of the BIPV system can be achieved.

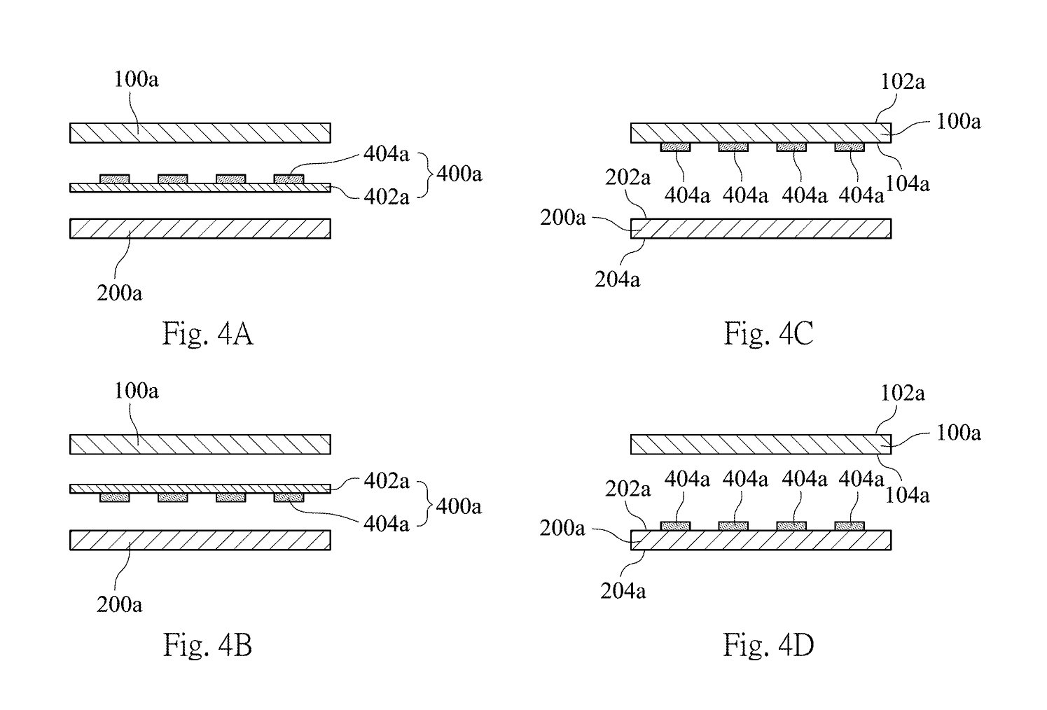

See FIG. 4A to FIG. 4D for further details, wherein FIG. 4A is a cross-sectional view of the photovoltaic conversion module 400a of FIG. 3 according to a first embodiment of the present disclosure, FIG. 4B is a cross-sectional view of the photovoltaic conversion module 400a of FIG. 3 according to a second embodiment of the present disclosure, FIG. 4C is a cross-sectional view of the photovoltaic conversion module 400a of FIG. 3 according to a third embodiment of the present disclosure, and FIG. 4D is a cross-sectional view of the photovoltaic conversion module 400a of FIG. 3 according to a fourth embodiment of the present disclosure. Firstly, as shown in FIG. 4A, the photovoltaic conversion module 400a is a solar module including a third substrate 402a and a plurality of solar cells 404a. The third substrate 402a is disposed between the first substrate 100a and the second substrate 200a, and the solar cells 404a are disposed on a side of the third substrate 402a facing the first substrate 100a.

In the method (not shown) of manufacturing the solar cells 404a, an electrode layer may be firstly formed onto the third substrate 402a. Afterwards, an absorption layer can be formed on the electrode layer, and then another electrode layer can be formed onto the absorption layer. Depending on various requirements, other materials or approaches may be subsequently used to obtain the complete structure of the solar cells 404a. The present disclosure improves the yield by using the first substrate with the second substrate, and hence how the photovoltaic conversion module 400a is manufactured is less important in the present disclosure. Furthermore, based on the photovoltaic (PV) material of the absorption layer, the solar cells 404a may be amorphous silicon solar cells, microcrystalline silicon solar cells, CdTe solar cells, CulnSe2 (CIS) solar cells, copper indium gallium diselenide (CICS) solar cells, organic photovoltaic (OPV) cells, dye sensitized solar cell (DSSC) solar cells, or a combination thereof.

As shown in FIG. 4B, in the second embodiment, although the photovoltaic conversion module 400a is a solar module as well, the solar cells 404a may be disposed on another side of the third substrate 402a facing the second substrate 200a.

See FIG. 4C, in the third embodiment, the photovoltaic conversion module 400a is a solar film disposed on the second arc surface 104a of the first substrate 100a. Specifically, in the third embodiment, the solar cells 404a of the photovoltaic conversion module 400a are directly formed on an inner side of the first substrate 100a (i.e., the second arc surface 104a resulted after the laminating step), and the arc-bending translucent assembly 1a can be obtained after the laminating step is performed to the first substrate 100a and the second substrate 200a. In the fourth embodiment of FIG. 4D, the solar cells 404a are formed on an outer side of the second substrate 200a (i.e., the third arc surface 202a resulted after the laminating step), and other parts are the same as the previous embodiment, which will not be repeated herein.

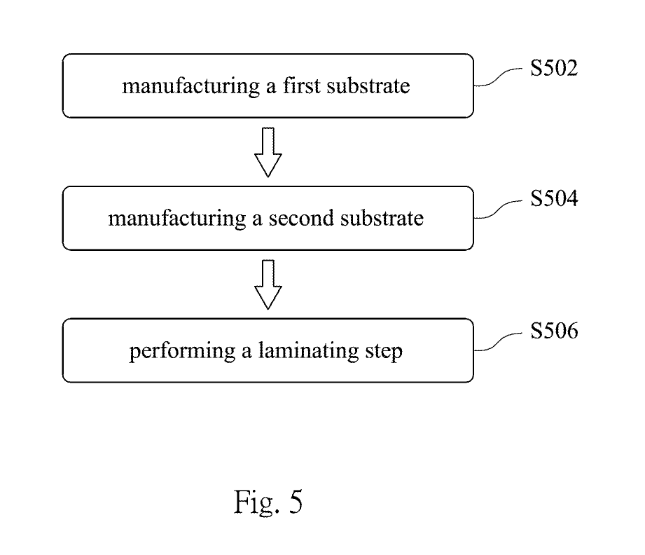

Subsequently, the manufacturing method of the arc-bending translucent assembly of the present disclosure will be illustrated with figures. See FIG. 5, which is a flow chart of the manufacturing method of the arc-bending translucent assembly of the present disclosure, wherein the method includes step S502, step S504, and step S506.

In step S502, a first substrate is manufactured. As mentioned before, the first substrate may be a glass substrate or a polymer substrate with a non-uniform thickness, and the first substrate may be manufactured by using a mold to process a plate to obtain a substrate with a non-uniform thickness, or by processing and attaching a plurality of the plates, but the present disclosure is not limited thereto. The thicknesses of the first substrate may be referred to the previous teachings, which will not be repeated herein.

In step S504, a second substrate is manufactured. The second substrate may be a glass substrate or a polymer substrate with a uniform thickness, and the manufacturing method thereof may depend on the material thereof. For example, if the second substrate is a polymer substrate (e.g., a plastic substrate), the second substrate may be made via an injection molding process.

In step S506, a laminating step is performed. Next, the aforementioned encapsulation material and the photovoltaic conversion module may be formed between the first substrate and the second substrate, and the first substrate and the second substrate can be combined via lamination to produce the arc-bending translucent assembly with various arcs. Specifically, a transmission rate of the arc-bending translucent assembly at a visible light region is higher than 10%, and a transmission rate of the arc-bending translucent assembly at wavelength of 550 nm is higher than 10%.

To sum up, the present disclosure proposes an arc-bending translucent assembly which is made by combining a first substrate having a non-uniform thickness with a second substrate having a uniform thickness, by which the breaking issue of the translucent assembly during a laminating process can be reduced, and hence the yield can be improved. Besides, the arc-bending translucent assembly may include a photovoltaic conversion module, such that the arc-bending translucent assembly may be deployed at the sunroof on the top of a vehicle, other car windows, or a building surface without additionally modifying the manufacturing equipment, such that the cost can be reduced while promoting the breadth of applications.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An arc-bending translucent assembly, comprising:
a first substrate, having a first thickness and a second thickness at two sides of the first substrate, wherein the first substrate has a first arc surface and a second arc surface opposite to the first arc surface, a third thickness exists between a first top of the first arc surface and a second top of the second arc surface, and the third thickness is larger than the first thickness or the second thickness; and
a second substrate, which is bent and disposed close to the second arc surface of the first substrate;
wherein two sides of the second arc surface are located at a plane, a normal distance exists between the first top of the first arc surface and the plane, and when the third thickness is A and the normal distance is B, the following condition is satisfied:
0 cm≦B−A≦5 cm.

2. The arc-bending translucent assembly of claim 1, wherein at least one of the first thickness and the second thickness is smaller than or equal to 10 mm.

3. The arc-bending translucent assembly of claim 1, wherein the first substrate and the second substrate are made of a glass or a polymer.

4. The arc-bending translucent assembly of claim 1, further comprising:
an encapsulation material, laminating the second substrate with the second arc surface of the first substrate.

5. The arc-bending translucent assembly of claim 4, wherein the encapsulation material is chosen from ethylene vinyl acetate copolymer, polyvinyl butyral, polyolefin elastomer copolymer, or polyvinyl fluoride.

6. The arc-bending translucent assembly of claim 1, wherein a transmittance rate of the arc-bending translucent assembly at visible light region is higher than 10%.

7. The arc-bending translucent assembly of claim 1, wherein a transmittance rate of the arc-bending translucent assembly at the wavelength of 550 nm is higher than 10%.

8. An arc-bending translucent assembly used at a top of a vehicle, comprising:
a first substrate, having a first thickness and a second thickness at two sides of the first substrate, wherein the first substrate has a first arc surface and a second arc surface opposite to the first arc surface, a third thickness exists between a first top of the first arc surface and a second top of the second arc surface, and the third thickness is larger than the first thickness or the second thickness;
a second substrate, which is bent and has a third arc surface and a fourth arc surface, wherein the third arc surface faces the second arc surface of the first substrate; and
a photovoltaic conversion module, disposed between the second arc surface of the first substrate and the third arc surface of the second substrate;
wherein two sides of the second arc surface are located at a plane, a normal distance exists between the first top of the first arc surface and the plane, and when the third thickness is A and the normal distance is B, the following condition is satisfied:
0 cm≦B−A≦5 cm.

9. The arc-bending translucent assembly used at the top of the vehicle of claim 8, wherein at least one of the first thickness and the second thickness is smaller than or equal to 10 mm.

10. The arc-bending translucent assembly used at the top of the vehicle of claim 8, wherein the first substrate and the second substrate are made of a glass or a polymer.

11. The arc-bending translucent assembly used at the top of the vehicle of claim 8, wherein the photovoltaic conversion module comprises a plurality of solar cells, and the solar cells are disposed on the second arc surface of the first substrate or the third arc surface of the second substrate.

12. The arc-bending translucent assembly used at the top of the vehicle of claim 8, wherein the photovoltaic conversion module comprises:
a third substrate, disposed between the first substrate and the second substrate; and
a plurality of solar cells, selectively disposed on a side of the third substrate facing the first substrate or disposed on another side of the third substrate facing the second substrate.

13. The arc-bending translucent assembly used at the top of the vehicle of claim 8, wherein the photovoltaic conversion module comprises at least one of an amorphous silicon solar cell, a microcrystalline silicon solar cell, a cadmium telluride solar cell, a copper indium selenide solar cell, a copper indium gallium diselenide solar cell, an organic photovoltaic cell, and a dye sensitized solar cell.

14. The arc-bending translucent assembly used at the top of the vehicle of claim 8, wherein a transmittance rate of the arc-bending translucent assembly at visible light region is higher than 10%.

15. The arc-bending translucent assembly used at the top of the vehicle of claim 8, wherein a transmittance rate of the arc-bending translucent assembly at the wavelength of 550 nm is higher than 10%.

16. A use of the arc-bending translucent assembly of claim 1, wherein the arc-bending translucent assembly is installed on a car window or on a building surface.

17. A manufacturing method of the arc-bending translucent assembly of claim 1, comprising:
manufacturing the first substrate;
manufacturing the second substrate; and
performing a laminating step to press and bond the second substrate with the first substrate.

18. The manufacturing method of the arc-bending translucent assembly of claim 17, wherein the first substrate is made by processing a plate or combining a plurality of the plates.
